(19) United States
(12) Patent Application Publication
(10) Pub. No.: US 2025/0365998 A1
(43) Pub. Date: Nov. 27, 2025

(54) CAPACITOR STRUCTURE AND MANUFACTURING METHOD THEREOF

(71) Applicant: Powerchip Semiconductor Manufacturing Corporation, Hsinchu (TW)

(72) Inventors: Hsin Tai, Hsinchu (TW); Po Cheng Chang, Hsinchu (TW); Wan-Lin Kuo, Hsinchu (TW); Mei Ling Ho, Hsinchu County (TW)

(73) Assignee: Powerchip Semiconductor Manufacturing Corporation, Hsinchu (TW)

(21) Appl. No.: 18/747,366

(22) Filed: Jun. 18, 2024

(30) Foreign Application Priority Data
May 27, 2024 (TW) 113119492

(51) Int. Cl. H01L 21/02; H01L 21/311

(52) U.S. Cl. CPC H10D 1/716; H01L 21/02236; H01L 21/31111

(57) ABSTRACT

Disclosed are a capacitor structure and a manufacturing method thereof. The capacitor structure includes a substrate, a first electrode, a first support layer, a second support layer, a capacitor dielectric layer and a second electrode. The substrate has a conductive device. The first electrode includes a first portion and a second portion connected to the first portion. The first portion is disposed on the conductive device, and the width of the first portion is greater than the width of the second portion. The first support layer is disposed on the substrate and surrounds the first portion of the first electrode. The second support layer is disposed above the first support layer and surrounds the second portion of the first electrode. The capacitor dielectric layer is disposed on the surface of the first electrode, the surface of the first support layer and the surface of the second support layer.

### CROSS-REFERENCE TO RELATED APPLICATION

This application claims the priority benefit of Taiwan application serial no. 113119492, filed on May 27, 2024. The entirety of the above-mentioned patent application is hereby incorporated by reference herein and made a part of this specification.

### BACKGROUND

### Technical Field

The present disclosure relates to a semiconductor structure and a manufacturing method thereof, and in particular, to a capacitor structure and a manufacturing method thereof.

### Description of Related Art

Dynamic random access memory (DRAM) mainly includes transistors and capacitors, wherein a capacitor serves as a storage node. A capacitor may be disposed above the transistor, and the capacitor and the transistor may be electrically connected through contacts and pads connected between the capacitor and the source/drain regions of the transistor.

In the current manufacturing process of dynamic random access memory, after the contacts and pads are formed, the lower electrode of the capacitor connected to the pads is formed. In order to increase the capacitance of the capacitor, it is required for the lower electrode to be tall in height. Therefore, at least a bottom support layer and an intermediate support layer surrounding the lower electrode may be provided around the lower electrode. In addition, the bottom support layer not only supports the lower electrode, but also covers the pads to prevent the pads from being damaged during the manufacturing process.

Generally speaking, the method of forming the lower electrode, the bottom support layer and the intermediate support layer may include the following steps. First, a bottom support layer, a first dielectric layer, an intermediate support layer and a second dielectric layer are formed in sequence. Then, a hole is formed in the bottom support layer, the first dielectric layer, the intermediate support layer and the second dielectric layer. Afterwards, a conductive material is formed in the hole to serve as a lower electrode. Then, the first dielectric layer and the second dielectric layer are removed through a wet etching process, while the bottom support layer and the intermediate support layer are retained. However, during the wet etching process, the bottom support layer is very likely to be removed due to over-etching, causing the pads to be damaged by etching.

In addition, since it is required for the lower electrode to be tall in height, the total thickness of the bottom support layer, the first dielectric layer, the intermediate support layer and the second dielectric layer needs to be thick. The limitation of the etching process for forming the hole results in the bottom portion of the formed hole having a small width. As a result, the contact area between the lower electrode and the pad is small, which leads to an increase in contact resistance between the lower electrode and the pad.

### SUMMARY

The present disclosure provides a capacitor structure and a manufacturing method thereof, wherein the lower electrode of the capacitor connected to the conductive device has a large width, thereby allowing a large contact area to be formed between the lower electrode and the conductive device.

The capacitor structure of the disclosure includes a substrate, a first electrode, a first support layer, a second support layer, a capacitor dielectric layer and a second electrode. The substrate has a conductive device disposed at the surface of the substrate. The first electrode includes a first portion and a second portion connected to the first portion. The first portion is disposed on the conductive device, and the width of the first portion is greater than the width of the second portion. The first support layer is disposed on the substrate and surrounds the first portion of the first electrode. The second support layer is disposed above the first support layer and surrounds the second portion of the first electrode. The capacitor dielectric layer is disposed on the surface of the first electrode, the surface of the first support layer and the surface of the second support layer. The second electrode is disposed on the capacitor dielectric layer.

In an embodiment of the capacitor structure of the present disclosure, the material of the first support layer includes SiC, SiCO or a combination thereof.

In an embodiment of the capacitor structure of the present disclosure, the first electrode is a cup-shaped electrode.

In an embodiment of the capacitor structure of the present disclosure, the first electrode is a columnar electrode.

In an embodiment of the capacitor structure of the present disclosure, the conductive device includes a pad.

In an embodiment of the capacitor structure of the present disclosure, the material of the second support layer includes silicon nitride doped with carbon or boron.

In an embodiment of the capacitor structure of the present disclosure, the first support layer covers a portion of the conductive device.

The manufacturing method of the capacitor structure of the present disclosure includes the following steps. A substrate is provided, wherein the substrate has a conductive device disposed at the surface of the substrate. A first electrode is formed on the conductive device, wherein the first electrode includes a first portion and a second portion connected to the first portion, and the width of the first portion is greater than the width of the second portion. A first support layer surrounding the first portion of the first electrode is formed on the substrate. A second support layer surrounding the second portion of the first electrode is formed above the first support layer. A capacitor dielectric layer is formed on the surface of the first electrode, the surface of the first support layer and the surface of the second support layer. A second electrode is formed on the capacitor dielectric layer.

In an embodiment of the manufacturing method of the capacitor structure of the present disclosure, the method of forming the first electrode, the first support layer and the second support layer includes the following steps. A first support material layer is formed on the substrate. A first dielectric layer is formed on the first support material layer. A second support material layer is formed on the first dielectric layer. A second dielectric layer is formed on the second support material layer. A hole is formed in the second dielectric layer, the second support material layer, the first dielectric layer and the first support material layer to expose the conductive device. An oxidation treatment is performed to oxidize a portion of the first support material layer. The oxidized first support material layer is removed to enlarge the hole. A first electrode material layer is formed in the hole. The first dielectric layer and the second dielectric layer are removed.

In an embodiment of the manufacturing method of the capacitor structure of the present disclosure, the material of the first support layer includes SiC, SiCO or a combination thereof.

In an embodiment of the manufacturing method of the capacitor structure of the present disclosure, the material of the first support layer includes SiC, and the oxidation treatment is performed through the use of oxygen-containing plasma.

In an embodiment of the manufacturing method of the capacitor structure of the present disclosure, the material of the first support layer includes SiCO, and the oxidation treatment is performed through the use of oxygen-containing plasma, nitrogen-hydrogen-containing plasma or helium-hydrogen-containing plasma.

In an embodiment of the method for manufacturing a capacitor structure of the present disclosure, the method of removing the oxidized first support material layer includes performing a wet etching process using a fluorine-containing etchant.

In an embodiment of the method for manufacturing a capacitor structure of the present disclosure, the fluorine-containing etchant includes hydrogen fluoride, ammonium fluoride, ammonium bifluoride or a combination thereof.

In an embodiment of the method for manufacturing a capacitor structure of the present disclosure, the materials of the first dielectric layer and the second dielectric layer include silicon oxide.

In an embodiment of the method for manufacturing a capacitor structure of the present disclosure, the method of removing the first dielectric layer and the second dielectric layer includes performing a wet etching process using a fluorine-containing etchant.

In an embodiment of the method for manufacturing a capacitor structure of the present disclosure, the first electrode material layer is formed on the side wall and the bottom portion of the hole and does not fully fill the hole.

In an embodiment of the method for manufacturing a capacitor structure of the present disclosure, the first electrode material layer fully fills the hole.

In an embodiment of the method for manufacturing a capacitor structure of the present disclosure, the material of the second support layer includes silicon nitride doped with carbon or boron.

In an embodiment of the method for manufacturing a capacitor structure of the present disclosure, the conductive device includes a pad.

Based on the above, in the capacitor structure of the present disclosure, the first electrode has a first portion with a large width, and the first portion is connected to the conductive device. Therefore, when the capacitor consisting of the first electrode, the capacitor dielectric layer and the second electrode is electrically connected to the conductive device through the first electrode, there may be a low contact resistance between the capacitor and the conductive device.

In addition, in the manufacturing method of the capacitor structure of the present disclosure, the first support layer surrounding the first portion of the first electrode will not be damaged during the etching process, thereby effectively protecting the underlying conductive device that does not need to be connected to the first electrode.

### BRIEF DESCRIPTION OF THE DRAWINGS

FIG. 1A to FIG. 1G are schematic cross-sectional views of the manufacturing process of the capacitor structure according to a first embodiment of the present disclosure.

FIG. 2 is a schematic cross-sectional view of a capacitor structure according to a second embodiment of the present disclosure.

### DESCRIPTION OF THE EMBODIMENTS

The embodiments are given below and described in detail with reference to the accompanying drawings. However, the provided embodiments are not intended to limit the scope of the present disclosure. In addition, the drawings are for illustrative purposes only and are not drawn to original size. To facilitate understanding, the same components will be identified with the same symbols in the following description.

The terms “include”, “comprise”, “have”, etc. used in the description are all open terms, which means “including but not limited to”.

When terms such as “first” and “second” are used to describe components, they are only used to distinguish these components from each other and do not limit the order or importance of these components. Therefore, in some cases, a first element may also be termed a second element, and the second element may also be termed a first element, without departing from the scope of the disclosure.

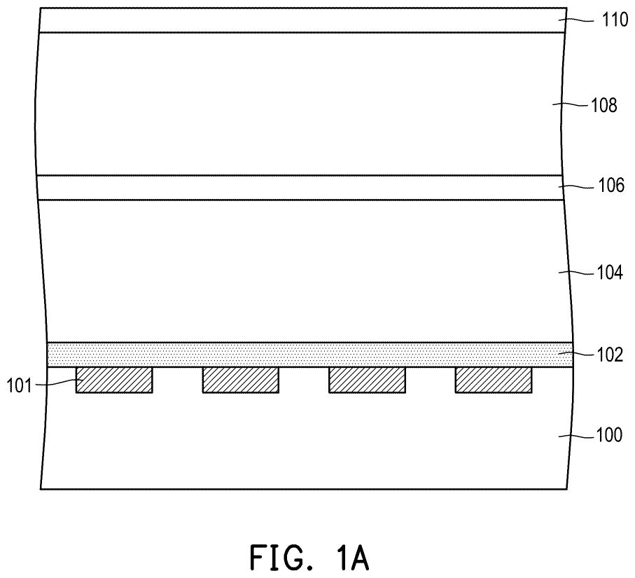

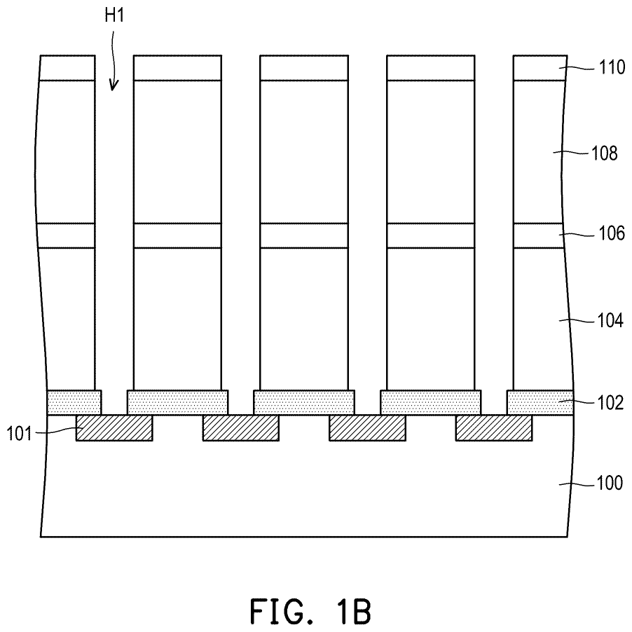

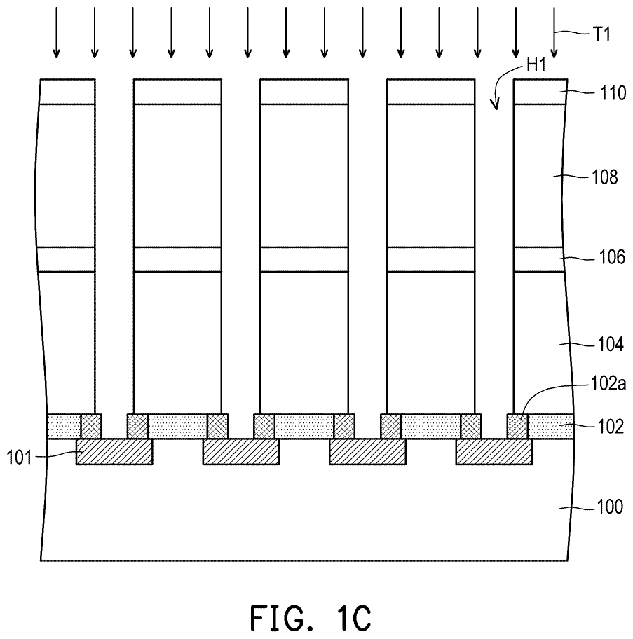

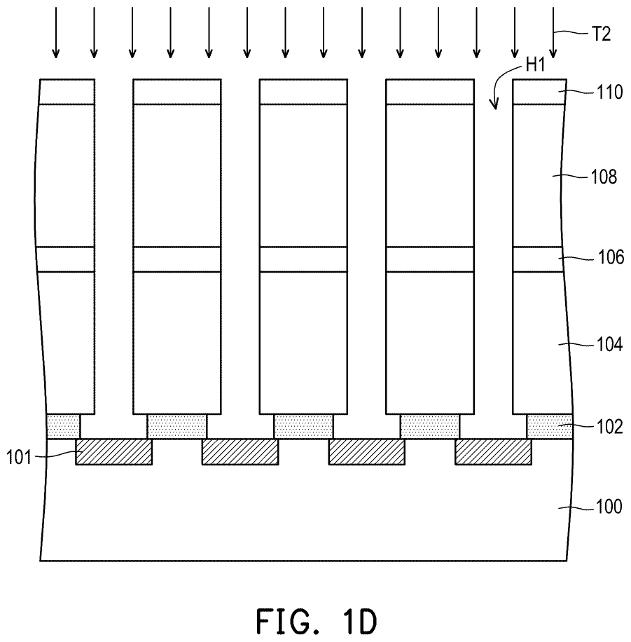

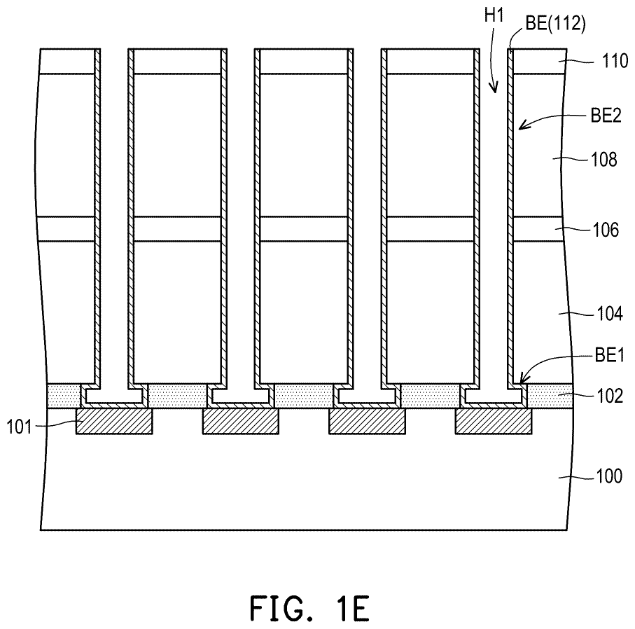

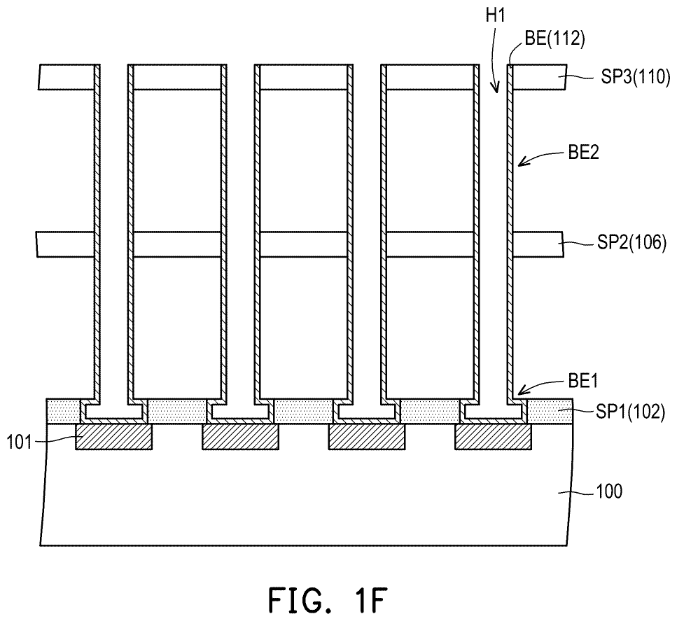

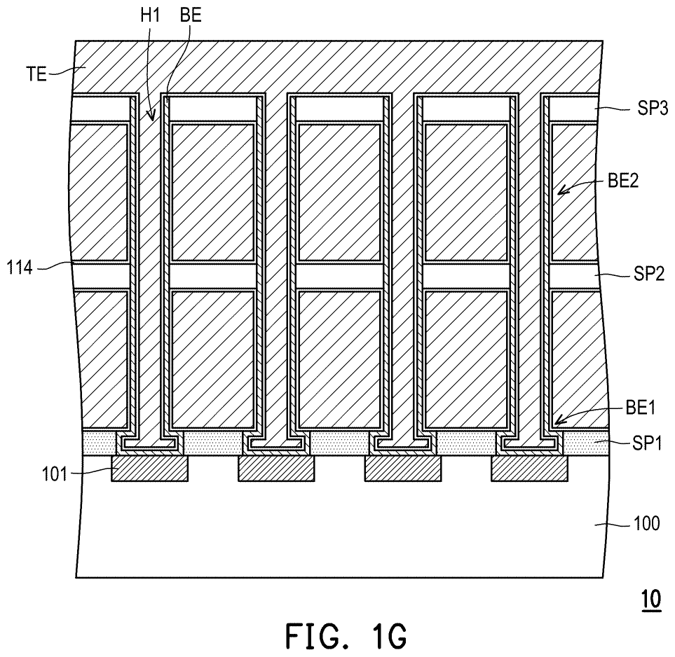

FIG. 1A to FIG. 1G are schematic cross-sectional views of the manufacturing process of the capacitor structure according to the first embodiment of the present disclosure.

First, please refer to FIG. 1A, a substrate 100 is provided. In this embodiment, the substrate 100 is a dielectric substrate, which may be a dielectric layer formed on a silicon substrate, and a conductive device 101 is formed on the surface of the dielectric layer. That is, the conductive device 101 is exposed at the surface of the substrate 100. In this embodiment, the conductive device 101 is a pad, but the disclosure is not limited thereto. In addition, a transistor and an interconnect structure connecting the transistor and the conductive device 101 are disposed on the silicon substrate, and the dielectric layer covers the transistor and the interconnect structure. In FIG. 1A, for clarity of illustration and convenience of explanation, only the conductive device 101 is shown. The detailed structures of the above-mentioned transistor and interconnect structure are commonly known to those skilled in the art and will not be described further here.

In FIG. 1A, the number of conductive device 101 is only exemplary, and the present disclosure is not limited thereto.

Next, the first support material layer 102, the first dielectric layer 104, the second support material layer 106, the second dielectric layer 108 and the third support material layer 110 are sequentially formed on the substrate 100. In other embodiments, depending on actual requirements, the third support material layer 110 may be omitted.

The material of the first support layer 102 may be SiC, SiCO or a combination thereof. The material of the first dielectric layer 104 may be silicon oxide. The material of the second support material layer 106 may be silicon nitride doped with carbon or boron. The material of the second dielectric layer 108 may be silicon oxide. The material of the third support material layer 110 may be silicon nitride doped with carbon or boron. The first support material layer 102, the second support material layer 106, and the third support material layer 110 are respectively used to form a bottom support layer, an intermediate support layer, and a top support layer that provide support for the lower electrode of the subsequently formed capacitor. Furthermore, in addition to serving as a bottom support layer that provides support for the lower electrode of the subsequently formed capacitor, the first support material layer 102 may also serve as a protective layer covering the conductive device 101.

Next, referring to FIG. 1B, the hole is formed in the third support material layer 110, the second dielectric layer 108, the second support material layer 106, the first dielectric layer 104 and the first support material layer 102. The position of the hole H1 corresponds to the position of the conductive device 101 to be connected to the lower electrode of the capacitor, so as to expose the conductive device 101 to be connected to the lower electrode of the capacitor. The hole H1 serves as a region forming the lower electrode of the capacitor. In this embodiment, the hole H1 exposes a portion of the top surface of the conductive device 101. Moreover, the conductive device 101 (not shown) that does not need to be connected to the lower electrode of the capacitor is not exposed by the hole H1.

In order to effectively increase the capacitance of the formed capacitor, it is required for the lower electrode to be tall in height, and therefore the hole H1 has a deep depth. Due to limitations of the etching process for forming the hole H1, it is difficult for the bottom portion of the formed hole H1 to have a large width. Furthermore, in this embodiment, the width of the bottom portion of the hole H1 is smaller than the width of the remaining portion of the hole H1 to avoid excessive exposure of the conductive device 101. Therefore, in this embodiment, a portion of the top surface of the first support material layer 102 is exposed by the hole H1, but the disclosure is not limited thereto. In other embodiments, the hole H1 may not expose the top surface of the first support material layer 102. In the case where the hole H1 exposes a portion of the top surface of the first support material layer 102, the subsequent oxidation treatment of the first support material layer 102 may be performed more smoothly, which will be described in detail later.

Then, referring to FIG. 1C, an oxidation process T1 is performed to oxidize a portion of the first support material layer 102. In this embodiment, plasma is used to perform an oxidation treatment T1 on a portion of the first support material layer 102 from the surface of the first support material layer 102 exposed by the hole H1.

In detail, when the first support material layer 102 is oxygen-free SiC, an oxygen-containing plasma may be used to perform the oxidation treatment T1, so that the surface of the first support material layer 102 exposed by the hole H1 faces the interior of the first support material layer 102, and a portion of the first support material layer 102 is oxidized to form a silicon oxide portion 102a. In this embodiment, the oxygen-containing plasma may be oxygen plasma, water vapor plasma, nitrogen-oxygen-containing plasma, or a combination thereof.

By controlling the time of the oxidation treatment T1, the amount of the formed silicon oxide portion 102a may be controlled. In this embodiment, the time of the oxidation treatment T1 is controlled so that the edge of the silicon oxide portion 102a does not exceed the edge of the underlying conductive device 101, that is, the entire silicon oxide portion 102a is located on the top surface of the conductive device 101.

In addition, when the first support material layer 102 is oxygen-containing SiCO, since the first support material layer 102 contains oxygen, an oxygen-free plasma may be used to perform the oxidation treatment T1, or the oxygen-containing plasma mentioned above may be used to perform oxidation treatment T1. In this embodiment, the oxygen-free plasma may be nitrogen-hydrogen-containing plasma, helium-hydrogen-containing plasma, or a combination thereof.

Next, referring to FIG. 1D, the oxidized first support material layer 102, that is, the silicon oxide portion 102a, is removed to enlarge the hole H1. After removing the silicon oxide portion 102a, the bottom portion of the hole H1 may further extend below the first dielectric layer 104, such that the width of the bottom portion of the hole H1 may be greater than the width of the remaining portion of the hole H1. In this way, the hole H1 may expose more area of the top surface of the conductive device 101.

In this embodiment, the method of removing the silicon oxide portion 102a is performed by using a fluorine-containing etchant to perform a wet etching process T2. The fluorine-containing etchant may be hydrofluoric acid (HF) or buffered hydrofluoric acid (BHF). Compared with the silicon oxide that forms the first dielectric layer 104 and the second dielectric layer 108, the above-mentioned fluorine-containing etchant has a greater etch rate for the silicon oxide formed by oxidation with SiC or SiCO. Accordingly, the wet etching process T2 may effectively remove the silicon oxide portion 102a without excessively damaging the first dielectric layer 104 and the second dielectric layer 108.

In addition, the above-mentioned fluorine-containing etchant has a relatively low etch rate for SiC or SiCO, so the first support material layer 102 is hardly removed. Therefore, by controlling the time of the wet etching process T2, the width of the bottom portion of the hole H1 may be accurately controlled. On the other hand, the conductive device 101 (not shown) that does not need to be connected to the lower electrode of the capacitor may still be covered by the first support material layer 102 to avoid damage.

Then, referring to FIG. 1E, a first electrode material layer 112 is formed in the hole H1. The first electrode material layer 112 is configured to form the lower electrode of the capacitor. In this embodiment, the first electrode material layer 112 may be a metal layer or a composite layer consisting of a metal layer and a nitride metal layer, but the disclosure is not limited thereto. For example, the first electrode material layer 112 is a titanium layer or a composite layer consisting of a titanium layer and a titanium nitride layer.

In this embodiment, the method of forming the first electrode material layer 112 may include the following steps. First, an electrode material layer is conformally formed to cover the side wall and the bottom portion of the hole H1 and the top surface of the third support material layer 110. Afterwards, the electrode material layer outside the hole H1 is removed. In this embodiment, the method of removing the electrode material layer outside the hole H1 is, for example, performing a chemical mechanical polishing (CMP) process to remove the electrode material layer on the top surface of the third support material layer 110.

In this way, the lower electrode BE (first electrode material layer 112) of the capacitor is formed in the hole H1. The lower electrode BE (first electrode material layer 112) is formed on the side wall and the bottom portion of the hole H1 and does not fully fill the hole H1. Accordingly, as shown in FIG. 1E, the lower electrode BE is a cup-shaped electrode, and the lower electrode BE includes a first portion BE1 located in the bottom portion of the hole H1 and a second portion BE2 connected to the first portion BE1. In this embodiment, since the bottom portion of the hole H1 has a large width and exposes more of the top surface of the conductive device 101, there may be a greater contact area between the lower electrode BE formed in the hole H1 and the conductive device 101 to further reduce the contact resistance between the lower electrode BE and the conductive device 101.

Next, referring to FIG. 1F, the first dielectric layer 104 and the second dielectric layer 108 are removed. The method of removing the first dielectric layer 104 and the second dielectric layer 108 includes performing a wet etching process using a fluorine-containing etchant. The above-mentioned fluorine-containing etchant is, for example, hydrogen fluoride, ammonium fluoride, ammonium bifluoride or a combination thereof. After the first dielectric layer 104 and the second dielectric layer 108 are removed, the first support material layer 102, the second support material layer 106 and the third support material layer 110 surrounding the lower electrode BE are retained. The first support material layer 102 serves as the first support layer SP1 (bottom support layer) surrounding the first portion BE1 of the lower electrode BE, the second support material layer 106 serves as the second support layer SP2 (intermediate support layer) surrounding the second portion BE2 of the lower electrode BE, and the third support material layer 110 serves as the third support layer SP3 (top support layer) surrounding the top portion of the lower electrode BE.

Afterwards, referring to FIG. 1G, a capacitor dielectric layer 114 is formed on the surface of the lower electrode BE, the surface of the first support layer SP1, the surface of the second support layer SP2 and the surface of the third support layer SP3. The material of the capacitor dielectric layer 114 may be a dielectric material with a high dielectric constant. For example, the capacitor dielectric layer 114 is a composite layer consisting of a zirconium oxide (ZrO₂) layer, an aluminium oxide (Al₂O₃) layer, and a zirconium oxide layer, but the disclosure is not limited thereto. After the capacitor dielectric layer 114 is formed, the upper electrode TE is formed on the capacitor dielectric layer 114. In this embodiment, the upper electrode TE fully fills the hole H1. In this embodiment, the upper electrode TE may be a metal layer or a composite layer consisting of a metal layer and a nitride metal layer, but the disclosure is not limited thereto. For example, the upper electrode TE is a titanium layer or a composite layer consisting of a titanium layer and a titanium nitride layer. In this way, the capacitor structure 10 of this embodiment is formed.

In the capacitor structure 10 of this embodiment, the lower electrode BE is surrounded by the first support layer SP1 made of SiC, SiCO or a combination thereof, and the lower electrode BE has a first portion BE1 with a large width. Accordingly, the capacitor consisting of the lower electrode BE, the capacitor dielectric layer 114 and the upper electrode TE is electrically connected to the conductive device 101 through the lower electrode BE, and there may be a low contact resistance between the capacitor and the conductive device 101.

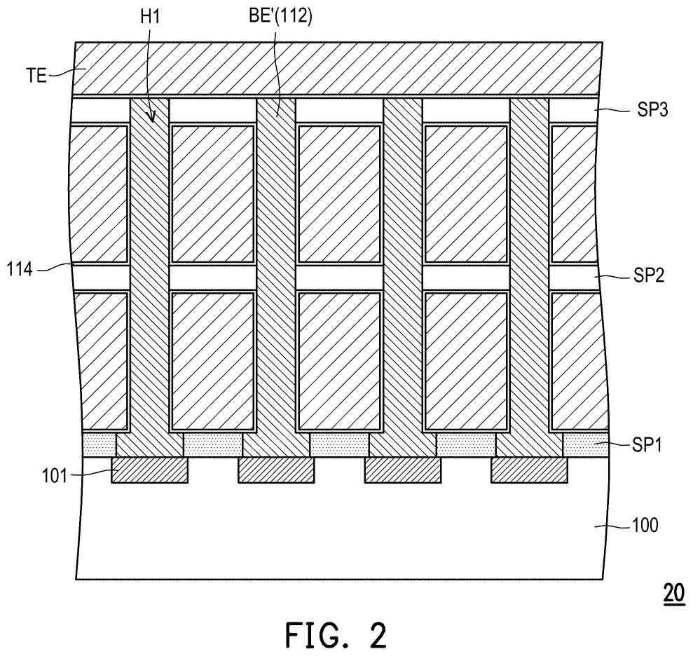

FIG. 2 is a schematic cross-sectional view of a capacitor structure according to a second embodiment of the present disclosure. In this embodiment, the same elements as those in the first embodiment will be denoted by the same reference symbols and will not be described again.

Please refer to FIG. 2. In the capacitor structure 20 of this embodiment, the lower electrode BE′ fully fills the hole H1. Therefore, in this embodiment, the lower electrode BE′ is a columnar electrode. In this embodiment, except that the first electrode material layer 112 is used to fully fill the hole H1 during the process of forming the lower electrode BE′, the manufacturing method of the capacitor structure 20 is substantially the same as the manufacturing method of the capacitor structure, and will not be further described here.

Although the present disclosure has been disclosed above through embodiments, it is not intended to limit the present disclosure. Anyone with ordinary knowledge in the technical field may make some modifications and refinement without departing from the spirit and scope of the present disclosure. Therefore, the scope to be protected by the present disclosure shall be determined by the scope of the appended claims.

What is claimed is:

1. A capacitor structure, comprising:
a substrate having a conductive device disposed at a surface of the substrate;
a first electrode comprising a first portion and a second portion connected to the first portion, wherein the first portion is disposed on the conductive device, and a width of the first portion is greater than a width of the second portion;
a first support layer disposed on the substrate and surrounding the first portion of the first electrode;
a second support layer disposed above the first support layer and surrounding the second portion of the first electrode;
a capacitor dielectric layer disposed on a surface of the first electrode, a surface of the first support layer and a surface of the second support layer; and
a second electrode disposed on the capacitor dielectric layer.

2. The capacitor structure according to claim 1, wherein a material of the first support layer comprises SiC, SiCO or a combination thereof.

3. The capacitor structure according to claim 1, wherein the first electrode is a cup-shaped electrode.

4. The capacitor structure according to claim 1, wherein the first electrode is a columnar electrode.

5. The capacitor structure according to claim 1, wherein the conductive device comprises a pad.

6. The capacitor structure according to claim 1, wherein a material of the second support layer comprises silicon nitride doped with carbon or boron.

7. The capacitor structure according to claim 1, wherein the first support layer covers a portion of the conductive device.

8. A manufacturing method of a capacitor structure, comprising:
providing a substrate, wherein the substrate has a conductive device disposed at a surface of the substrate;
forming a first electrode on the conductive device, wherein the first electrode comprises a first portion and a second portion connected to the first portion, and a width of the first portion is greater than a width of the second portion;
forming a first support layer surrounding the first portion of the first electrode on the substrate;
forming a second support layer surrounding the second portion of the first electrode above the first support layer;
forming a capacitor dielectric layer on a surface of the first electrode, a surface of the first support layer and a surface of the second support layer; and
forming a second electrode on the capacitor dielectric layer.

9. The manufacturing method of the capacitor structure according to claim 8, wherein the method of forming the first electrode, the first support layer and the second support layer comprises the following:
forming a first support material layer on the substrate;
forming a first dielectric layer on the first support material layer;
forming a second support material layer on the first dielectric layer;
forming a second dielectric layer on the second support material layer;
forming a hole in the second dielectric layer, the second support material layer, the first dielectric layer and the first support material layer to expose the conductive device;
performing an oxidation treatment to oxidize a portion of the first support material layer;
removing the oxidized first support material layer to enlarge the hole;
forming a first electrode material layer in the hole; and
removing the first dielectric layer and the second dielectric layer.

10. The manufacturing method of the capacitor structure according to claim 9, wherein a material of the first support layer comprises SiC, SiCO or a combination thereof.

11. The manufacturing method of the capacitor structure according to claim 10, wherein the material of the first support layer comprises SiC, and the oxidation treatment is performed through use of an oxygen-containing plasma.

12. The manufacturing method of the capacitor structure according to claim 10, wherein the material of the first support layer comprises SiCO, and the oxidation treatment is performed through use of an oxygen-containing plasma, a nitrogen-hydrogen-containing plasma or a helium-hydrogen-containing plasma.

13. The manufacturing method of the capacitor structure according to claim 9, wherein the method of removing the oxidized first support material layer comprises performing a wet etching process using a fluorine-containing etchant.

14. The manufacturing method of the capacitor structure according to claim 13, wherein the fluorine-containing etchant comprises hydrogen fluoride, ammonium fluoride, ammonium bifluoride or a combination thereof.

15. The manufacturing method of the capacitor structure according to claim 9, wherein materials of the first dielectric layer and the second dielectric layer comprise silicon oxide.

16. The manufacturing method of the capacitor structure according to claim 15, wherein the method of removing the first dielectric layer and the second dielectric layer comprises performing a wet etching process using a fluorine-containing etchant.

17. The manufacturing method of the capacitor structure according to claim 9, wherein the first electrode material layer is formed on a side wall and a bottom portion of the hole and does not fully fill the hole.

18. The manufacturing method of the capacitor structure according to claim 9, wherein the first electrode material layer fully fills the hole.

19. The manufacturing method of the capacitor structure according to claim 8, wherein a material of the second support layer comprises silicon nitride doped with carbon or boron.

20. The manufacturing method of the capacitor structure according to claim 8, wherein the conductive device comprises a pad.
